(19) United States
(12) Patent Application Publication
(10) Pub. No.: US 2026/0164737 A1
(43) Pub. Date: Jun. 11, 2026

(54) SEMICONDUCTOR DEVICE

(71) Applicant: Samsung Electronics Co., Ltd., Suwon-si (KR)

(72) Inventors: Inhyun SONG, Suwon-si (KR); Keun Hwi CHO, Suwon-si (KR); Jooho JUNG, Suwon-si (KR); Donghun KIM, Suwon-si (KR); Taewoo UHM, Suwon-si (KR); Eunguk CHUNG, Suwon-si (KR)

(21) Appl. No.: 19/218,789

(22) Filed: May 27, 2025

(30) Foreign Application Priority Data
Dec. 5, 2024 (KR) 10-2024-0179931

(51) Int. Cl. H10D 62/60; H10D 30/00; H10D 30/01; H10D 30/43; H10D 62/10

(52) U.S. Cl. CPC H10D 62/60; H10D 30/014; H10D 30/0191; H10D 30/43; H10D 30/502; H10D 62/121

(57) ABSTRACT

Provided is a semiconductor device, including a substrate including a first well having a first conductivity type and a second well having a second conductivity type that is opposite the first conductivity type, a first impurity pattern of the first conductivity type disposed on the first well, a second impurity pattern of the second conductivity type disposed on the second well, a first passivation pattern disposed between the first impurity pattern and the second impurity pattern on a first surface of the substrate, and a second passivation pattern disposed on a second surface of the substrate opposite to the first surface of the substrate.

### CROSS-REFERENCE TO RELATED APPLICATION

This application claims priority under 35 U.S.C. § 119 to Korean Patent Application No. 10-2024-0179931, filed in the Korean Intellectual Property Office on Dec. 5, 2024, the entire contents of which are hereby incorporated by reference.

### BACKGROUND

### Technical Field

The present disclosure relates to a semiconductor device.

### Description of Related Art

Semiconductor devices can be used as components for storing data or controlling electrical signals in electronic devices, and various types of semiconductor devices are manufactured in order to achieve such purposes. Additionally, components of passive devices can be formed in semiconductor devices. For example, a passive device such as a resistor, a capacitor, or an inductor may be part of an integrated circuit used to perform signal conversion, stabilization, and signal correction in a semiconductor device.

The demand for electronic devices with enhanced performance and function continues to increase, which in turn requires high-performance characteristics from the semiconductor devices. To meet this demand, various technologies are being developed for the miniaturization, increased efficiency, and improved reliability of the passive devices. Accordingly, technologies and methods for manufacturing passive devices with excellent performance and improved reliability are being researched.

### SUMMARY

The present disclosure provides a semiconductor device with improved reliability and electrical performance.

According to some embodiments of the present disclosure, a semiconductor device may include a substrate including a first well having a first conductivity type and a second well having a second conductivity type that is opposite the first conductivity type, a first impurity pattern of the first conductivity type disposed on the first well, a second impurity pattern of the second conductivity type disposed on the second well, a first passivation pattern disposed between the first impurity pattern and the second impurity pattern on a first surface of the substrate, and a second passivation pattern disposed on a second surface opposite to the first surface of the substrate.

According to some embodiments, a semiconductor device may include a substrate including a first well having a first conductivity type and a second well having a second conductivity type, first and second impurity patterns of the first conductivity type disposed on the first well, third and fourth impurity patterns of the second conductivity type disposed on the second well, a first passivation pattern disposed on a first surface of the substrate, and a second passivation pattern disposed on a second surface opposite to the first surface of the substrate, the first passivation pattern may be disposed between the first impurity pattern and the third impurity pattern with the first impurity pattern at a first side of the first passivation pattern and the third impurity pattern at a second side of the first passivation pattern opposite the first side.

According to some embodiments, a semiconductor device may include a substrate including a fin region including a first well of a first conductivity type and a second well of a second conductivity type, in which the fin region may extend in a first direction, a first impurity pattern of the first conductivity type disposed on the first well, a second impurity pattern of the second conductivity type disposed on the second well, a first passivation pattern disposed on a first surface of the substrate and extending lengthwise in a second direction intersecting with the first direction, a second passivation pattern disposed on a second surface opposite to the first surface of the substrate, and an insulating pattern disposed on the first passivation pattern, in which the first passivation pattern may be disposed between the first impurity pattern and the second impurity pattern in the second direction, the first passivation pattern may include a first portion extending in a first direction and disposed on the first surface of the substrate, a second portion extending from a first end of the first portion along a side surface of the first impurity pattern in a third direction intersecting with the first and second directions, and a third portion extending from a second end of the first portion along a side surface of the second impurity pattern in the third direction, and the insulating pattern may be disposed between the second portion and the third portion.

According to some embodiments of the present disclosure, by removing a channel pattern from the intermediate structure of the semiconductor device in which the gate electrode and the channel pattern are formed, and arranging the passivation patterns on the front and back sides of the substrate, the reliability and electrical performance of the semiconductor device can be improved.

According to some embodiments of the present disclosure, by removing a channel pattern and a gate electrode from the intermediate structure of the semiconductor device in which the gate electrode and the channel pattern are formed, and arranging the passivation patterns on the front and back sides of the substrate, the reliability and electrical performance of the semiconductor device can be improved.

The effects and benefits that can be obtained through the present disclosure are not limited to those described above. Technical effects not mentioned herein will be clearly understood by those skilled in the art from the description of the present disclosure described below.

### BRIEF DESCRIPTION OF THE DRAWINGS

The above and other objects, features and advantages of the present disclosure will become more apparent to those of ordinary skill in the art by describing in detail example aspects thereof with reference to the accompanying drawings, in which:

FIG. 1 is an example plan of a semiconductor device according to some embodiments;

FIG. 2 is a cross-sectional view taken along line A-A of FIG. 1;

FIG. 3 is a cross-sectional view taken along line B-B of FIG. 1;

FIG. 4 is a cross-sectional view of a semiconductor device according to some embodiments;

FIG. 5 is a cross-sectional view of a semiconductor device according to some embodiments;

FIG. 6 is a cross-sectional view of a semiconductor device according to some embodiments;

FIG. 7 is a cross-sectional view of a semiconductor device according to some embodiments;

FIG. 8 is a cross-sectional view of a semiconductor device according to some embodiments;

FIGS. 9 and 10 are cross-sectional views of a semiconductor device according to some embodiments;

FIG. 11 is a cross-sectional view of a semiconductor device according to some embodiments;

FIG. 12 is a cross-sectional view of a semiconductor device according to some embodiments;

FIG. 13 is a cross-sectional view of a semiconductor device according to some embodiments;

FIG. 14 is a cross-sectional view of a semiconductor device according to some embodiments;

FIGS. 15 to 21 are cross-sectional views of a semiconductor device according to some embodiments;

FIGS. 22 to 24 are cross-sectional views of intermediate stages of a semiconductor device illustrating a method for manufacturing a semiconductor device according to some embodiments;

FIGS. 25 and 26 are cross-sectional views of intermediate stages of a semiconductor device illustrating a method for manufacturing a semiconductor device according to some embodiments; and

FIGS. 27 to 32 are cross-sectional views of intermediate stages of a semiconductor device illustrating a method for manufacturing a semiconductor device according to some embodiments.

### DETAILED DESCRIPTION

A semiconductor device and a method for manufacturing the same according to some embodiments will be described in detail with reference to the drawings in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. Items described in the singular herein may be provided in plural, as can be seen, for example, in the drawings. Thus, the description of a single item that is provided in plural should be understood to be applicable to the remaining plurality of items unless context indicates otherwise.

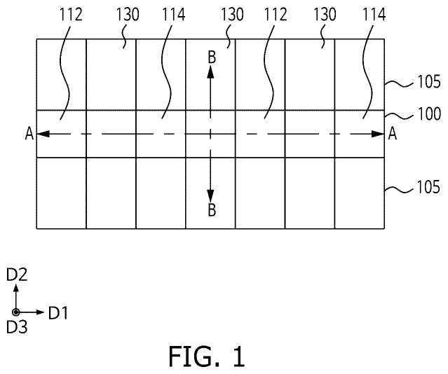

As used herein, a semiconductor device may refer to a device formed with semiconductor materials such any of the various devices such as shown in FIGS. 1-21, which may be a sub-component of a larger semiconductor device such as, for example, a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. The semiconductor device may be a passive semiconductor device such as a diode, capacitor, inductor, or resistor.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Additionally, when a first element is referred to as being on a “surface” of a second element, it is to be understood that the first element at least partially overlaps the surface of second element in a direction normal to the surface of the second element. The first element may be directly or indirectly on the surface of the second element as described above.

As used herein, components described as being “electrically connected” are configured such that an electrical signal can be transferred from one component to the other (although such electrical signal may be attenuated in strength as it is transferred and may be selectively transferred).

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Hereinafter, in drawings illustrated in FIGS. 1 to 32, a first direction D1, a second direction D2, and a third direction D3 intersect with each other (e.g., the first direction D1, second direction D2, and third direction D3 may form a coordinate system). The first direction D1 and the second direction D2 may define a first plane (e.g., a horizontal plane), the second direction D2 and the third direction D3 may define a second plane (e.g., a first vertical plane extending in the second direction), and the first direction D1 and the third direction D3 may form a third plane (e.g., a second vertical plane extending in the first direction). The directions may be relative to a base surface such as a lower surface of a substrate in which the horizontal plane is parallel to the base surface.

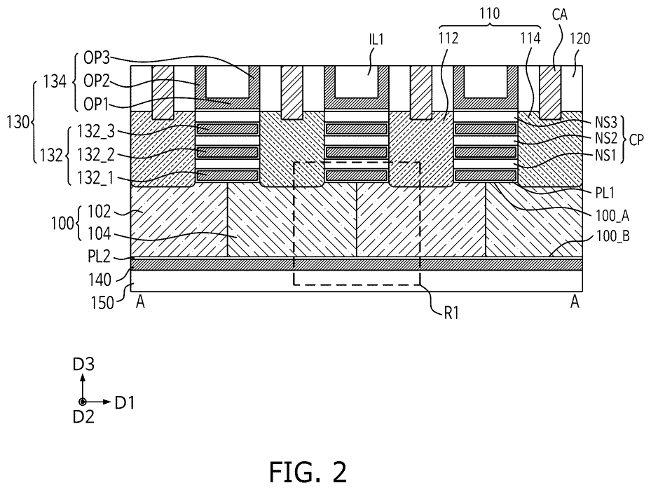

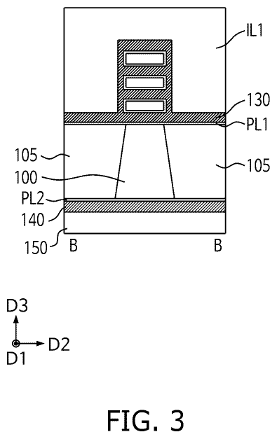

FIG. 1 is an example plan view provided to explain a semiconductor device according to some embodiments. FIG. 2 is a cross-sectional view taken along line A-A of FIG. 1. FIG. 3 is a cross-sectional view taken along line B-B of FIG. 1.

The semiconductor device according to some embodiments may include a passive device having a PN junction. For example, the semiconductor device may include a PN diode. For example, the semiconductor device may include a lateral PN diode having a horizontal structure.

Referring to FIGS. 1 to 3, the semiconductor device according to some embodiments may include a substrate 100, an impurity pattern 110, a channel pattern CP, a first passivation pattern 130, a second passivation pattern 140, a first passivation insulating film PL1, a second passivation insulating film PL2, and other elements, which may not be described in further detail.

The substrate 100 may be a bulk silicon or a silicon-on-insulator (SOI) substrate. Alternatively, the substrate 100 may include silicon germanium (SiGe), silicon germanium on insulator (SGOI), indium antimony, lead telluride compound, indium arsenide, indium phosphide, gallium arsenide, or gallium antimony, but the disclosure is not limited thereto.

The substrate 100 may have a fin shape and the fin shape may extend lengthwise in the first direction D1. In some embodiments, the substrate 100 may have a plate shape and include a fin region formed to protrude in the third direction D3 from the substrate 100 and the fin region may extend lengthwise in the first direction. In the present disclosure, a fin region may refer to a fin shaped region protruding from the fin-shaped substrate 100 or a fin shaped region protruding from the plate-shaped substrate 100.

The substrate 100 may include a first surface 100_A (e.g., an upper surface) and a second surface 100_B (a lower or base surface) opposite to the first surface 100_A. The first surface 100_A of the substrate 100 may refer to a surface on which the first passivation pattern 130 and the channel pattern CP are disposed. The first surface 100_A of the substrate 100 may represent an upper surface of the fin region. The surface 100_B of the substrate 100 may be a surface on which the second passivation pattern 140 is disposed. The first surface 100_A of the substrate 100 may be referred to as a front side of the substrate 100. The second surface 100_B of the substrate 100 may be referred to as a back side of the substrate 100.

The fin region of the substrate 100 may include a first well 102 having a first conductivity type and a second well 104 having a second conductivity type. The first conductivity type and the second conductivity type may be opposite to each other (e.g., may be opposite conductivity types). The first well 102 and the second well 104 may form a PN junction structure. For example, the first well 102 and the second well 104 may be arranged in series on the fin region of the substrate 100. The first well 102 may include p-type impurities (e.g., the first well 102 may have had p-type impurities injected into it). The second well 104 may include n-type impurities (e.g., the second well 104 may have had n-type impurities injected into it). In another example, the first well 102 may include n-type impurities instead of p-type impurities and the second well 104 may include p-type impurities in place of n-type impurities. The n-type impurities may include at least one of phosphorus (P), arsenic (As), or antimony (Sb). Further, the p-type impurities may include at least one of boron (B), gallium (Ga), or aluminum (Al). However, the disclosure is not limited to the above.

A device isolation film 105 may be disposed on opposite side surfaces of the substrate 100 in the second direction D2 and extend in the first direction D1 along the side surfaces. The device isolation film 105 may include oxide, nitride, nitride oxide, or a combination thereof, but the disclosure is not limited thereto. The device isolation film 105 may include a single film or a plurality of films.

The impurity patterns 110 may be disposed on the wells 102 and 104 of the substrate 100. For example, the impurity patterns 110 may include a first impurity pattern 112 and a second impurity pattern 114. The first impurity pattern 112 may be disposed on the first well 102, and the second impurity pattern 114 may be disposed on the second well 104. The first impurity pattern 112 and the second impurity pattern 114 may be spaced apart from each other in the first direction D1.

The impurity patterns 110 may be formed on a surface of the substrate 100 and on at least one side surface of the channel pattern CP. The impurity patterns 110 may be epitaxial patterns formed by a selective epitaxial growth process using the substrate 100 and the channel pattern CP as seeds. The impurity patterns 110 may be configured to have a diode role of the PN junction structure formed between the first well 102 and the second well 104. For example, the impurity patterns 110 may serve as a path for electrical connection between a contact CA and the first and second wells 102 and 104.

The impurity patterns 110 may include semiconductor materials. The impurity pattern 110 may include, for example, an elemental semiconductor material such as silicon (Si) or germanium (Ge). In addition, the impurity pattern 110 may include, for example, a binary compound or a ternary compound including at least two or more of carbon (C), silicon (Si), germanium (Ge), tin (Sn), or a compound of these doped with a group IV element. For example, the impurity pattern 110 may include silicon (Si), silicon-germanium (SiGe), germanium (Ge), silicon carbide (SiC), etc., but the disclosure is not limited thereto.

The conductivity type of the first impurity pattern 112 and the conductivity type of the second impurity pattern 114 may be opposite to each other (e.g., opposite conductivity types). For example, the first impurity pattern 112 may include p-type impurities. Further, the second impurity pattern 114 may include n-type impurities. In another example, the first impurity pattern 112 may include n-type impurities instead of p-type impurities and second impurity pattern 114 may include p-type impurities instead of n-type impurities. The n-type impurities may include materials such as phosphorus (P), arsenic (As), or antimony (Sb). Further, the p-type impurities may include a material such as boron (B), gallium (Ga), or aluminum (Al). However, the disclosure is not limited to the above.

A first interlayer insulating films 120 may be disposed on the impurity patterns 110. The first interlayer insulating films 120 may cover a portion of each of the first impurity pattern 112 and the second impurity pattern 114. The first interlayer insulating films 120 may include at least one of, for example, silicon oxide (SiO), silicon nitride (SiN), or silicon oxynitride (SiON), but the disclosure is not limited thereto.

The channel pattern CP may be disposed on the first surface 100_A of the substrate 100. According to some embodiments, the channel pattern CP may include a plurality of nanosheets NS1, NS2, and NS3. For example, the channel pattern CP may include a plurality of nanosheets NS1, NS2, and NS3 on the substrate 100, which nanosheets NS1, NS2, and NS3 may be spaced apart from each other and stacked in the third direction D3. However, the disclosure is not limited to the above, and the channel pattern CP may include a plurality of nanowires (e.g., in place of the plurality of nanosheets). In addition, although the channel pattern CP including three sheet patterns is illustrated, the disclosure is not limited thereto. Unlike the illustration, the channel pattern CP may include two or less, or four or more sheet patterns.

The channel pattern CP may include one of an elemental semiconductor material such as silicon (Si) or silicon germanium (SiGe), a group IV-IV compound semiconductor, or a group III-V compound semiconductor. For example, the group IV-IV compound semiconductor may be a binary compound or a ternary compound including at least two or more of carbon (C), silicon (Si), germanium (Ge), tin (Sn), or a compound doped with a group IV element. The group III-V compound semiconductor may be, for example, one of a binary compound, a ternary compound, or a quaternary compound formed by a combination of at least one of aluminum (Al), gallium (Ga) and indium (In) as a group III element and one of phosphorus (P), arsenic (As), and antimony (Sb) as a group V element.

The first passivation pattern 130 may be disposed on the first surface 100_A of the substrate 100. For example, the first passivation pattern 130 may be disposed on the wells 102 and 104 of the substrate 100 and on the device isolation film 105. The first passivation pattern 130 may be disposed between the first impurity pattern 112 and the second impurity pattern 114 (e.g., may separate the first impurity pattern 112 and the second impurity pattern 114 in the first direction).

According to some embodiments, the first passivation pattern 130 may include an inner passivation pattern 132 and an outer passivation pattern 134. The inner passivation pattern 132 may be disposed on the first surface 100_A of the substrate 100. The inner passivation pattern 132 may be disposed between the first impurity pattern 112 and the second impurity pattern 114. The inner passivation pattern 132 may surround the plurality of nanosheets NS1, NS2, and NS3. The inner passivation pattern 132 may include a plurality of passivation layers 132_1, 132_2, and 132_3 in a cross-section (e.g., A-A cross-section) of the semiconductor device. The plurality of passivation layers 132_1, 132_2, and 132_3 may be alternately stacked with the plurality of nanosheets NS1, NS2, and NS3 (e.g., may alternate between a passivation layer and a nanosheet in the third direction D3).

The outer passivation pattern 134 may be disposed on the channel pattern CP. For example, the outer passivation pattern 134 may be disposed on an upper surface of the uppermost nanosheet NS3 among the plurality of nanosheets of the channel pattern CP. The outer passivation pattern 134 may be disposed at a side surface of the first interlayer insulating film 120.

According to some embodiments, the outer passivation pattern 134 may include a first portion OP1 disposed on the uppermost nanosheet NS3 of the channel pattern CP, a second portion OP2 extending from a first end of the first portion OP1 and intersecting with the first portion OP1 (e.g., in the third direction D3), and a third portion OP3 extending from a second end of the first portion OP1 and intersecting with the first portion OP1 (e.g., the second portion OP2 and the third portion OP3 may extend from the first portion OP1 in the third direction D3 at opposite ends of the first portion OP1 in the first direction).

According to some embodiments, the semiconductor device may further include a first insulating pattern IL1. The first insulating pattern IL1 may be disposed on the first passivation pattern 130. The first insulating pattern IL1 may be disposed between the second portion OP2 and the third portion OP3. For example, in a cross-section (e.g., A-A cross-section) of the semiconductor device, a portion of the first insulating pattern IL1 may be disposed between the second portion OP2 and the third portion OP3 of the outer passivation pattern 134. The first insulating pattern IL1 may include at least one of silicon oxide (SiO), silicon nitride (SiN), or silicon oxynitride (SiON), but the disclosure is not limited thereto.

The second passivation pattern 140 may be disposed on the second surface 100_B of the substrate 100. For example, the second passivation pattern 140 may be disposed on the wells 102 and 104 of the substrate 100 and the device isolation film 105 (e.g., on a lower surface of the wells 102 and 104 and the device isolation film 105). In another example, the second passivation pattern 140 may be disposed on the second surface 100_B of the plate-shaped substrate 100.

In some embodiments, the passivation patterns 130 and 140 may include at least one of a positive fixed charge layer or a negative fixed charge layer. However, the disclosure is not limited to the above. For example, the passivation patterns 130 and 140 may not have a specific charge.

The passivation patterns 130 and 140 of the negative fixed charge layer may include a high-k material having a higher dielectric constant than that of silicon oxide. For example, the high-k material may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

In other aspects, the passivation patterns 130 and 140 of the positive fixed charge layer may include at least one of silicon oxide, silicon oxynitride, silicon nitride, or silicon carbide, but the disclosure is not limited thereto.

The first passivation insulating film PL1 may be disposed on the first passivation pattern 130. For example, the first passivation insulating film PL1 may be disposed between the first passivation pattern 130 and the channel pattern CP. The first passivation insulating film PL1 may be disposed between the first passivation pattern 130 and the first impurity pattern 112, and disposed between the first passivation pattern 130 and the second impurity pattern 114. The first passivation insulating film PL1 may be disposed between the first passivation pattern 130 and the first surface 100_A of the substrate 100. In this case, the first passivation insulating film PL1 may be disposed on an upper surface of each of the wells 102 and 104 and the device isolation film 105. The first passivation pattern 130 may be prevented from contact with the channel pattern CP and the impurity patterns 112 and 114 by the first passivation insulating film PL1.

The second passivation insulating film PL2 may be disposed on the second passivation pattern 140. For example, the second passivation insulating film PL2 may be disposed between the second passivation pattern 140 and the second surface 100_B of the substrate 100. In embodiments in which the substrate 100 has a fin shape, the second passivation insulating film PL2 may be disposed on a lower surface of each of the wells 102 and 104 and the device isolation film 105. In embodiments in which the substrate 100 has a plate shape and the fin region is formed on the front side of the substrate 100, the second passivation insulating film PL2 may be disposed on the second surface 100_B of the substrate 100. The second passivation pattern 140 may be prevented from contact with the substrate 100 by the second passivation insulating film PL2.

The passivation insulating films PL1 and PL2 may include at least one of silicon oxide, silicon oxynitride, silicon nitride, or silicon carbide, but the disclosure is not limited thereto.

The second interlayer insulating film 150 may be disposed on the second passivation pattern 140. The second interlayer insulating film 150 may include at least one of silicon oxide (SiO), silicon nitride (SiN), or silicon oxynitride (SiON), but the disclosure is not limited thereto.

The contact CA may be disposed on the impurity patterns 112 and 114 and connected to the impurity patterns 112 and 114 (e.g., a first contact CA may be connected to the first impurity pattern and a second contact CA may be connected to the second impurity pattern). A contact CA may contact the impurity pattern to which it is connected. The contact CA may include at least one of a metal, a metal alloy, a conductive metal nitride, a metal silicide, a doped semiconductor material, a conductive metal oxide, and a conductive metal oxynitride.

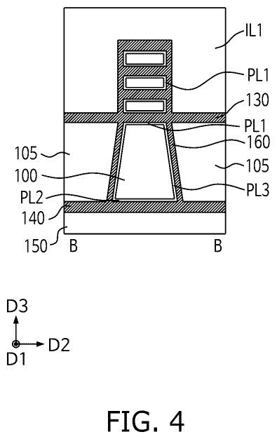

FIG. 4 is a cross-sectional view of a semiconductor device according to some embodiments. For reference, FIG. 4 may correspond to a cross-sectional view taken along line B-B in FIG. 1. For convenience of explanation, a description of features that are the same as or substantially similar to those described previously may be omitted and different configurations from those described in FIGS. 1 to 3 will be mainly explained.

According to some embodiments, the semiconductor device may further include a third passivation pattern 160 and a third passivation insulating film PL3.

The third passivation pattern 160 may be disposed on a side surface of the fin region of the substrate 100. For example, the third passivation pattern 160 may extend along a side surface of the substrate 100. The fin region may extend lengthwise in the first direction D1, and the side surface of the fin region may be a side surface in the second direction D2 of the substrate 100. Further, a width of the upper surface of the fin region may be narrower than that of a lower surface of the fin region (e.g., the fin region may be tapered in the third direction D3).

The third passivation insulating film PL3 may be disposed between the third passivation pattern 160 and the substrate 100. For example, the third passivation insulating film PL3 may be disposed between the third passivation pattern 160 and the side surface of the fin region of the substrate 100. The third passivation pattern 160 may be prevented from contact with the substrate 100 by the third passivation insulating film PL3.

In some embodiments, the third passivation pattern 160 may be connected to the first passivation pattern 130. Further, the third passivation pattern 160 may be connected to the second passivation pattern 140. Accordingly, the first passivation pattern 130, the second passivation pattern 140, and the third passivation pattern 160 may be integrally formed with one another (e.g., formed in the same process without a process break).

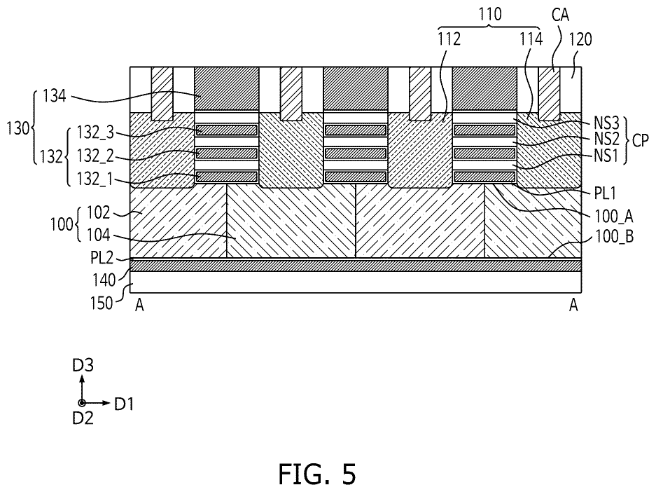

FIG. 5 is a cross-sectional view of a semiconductor device according to some embodiments. For reference, FIG. 5 may be a diagram corresponding to a cross-sectional view taken along line A-A of FIG. 1. The semiconductor device of FIG. 5 may be the same or substantially the same as the semiconductor device described with reference to FIGS. 1 to 4, except for the shape of the outer passivation pattern 134. For convenience of explanation, a description of features that are the same as or substantially the same to those described previously may be omitted and different configurations from those described in FIGS. 1 to 4 will be mainly explained.

According to some embodiments, the outer passivation pattern 134 may fill a space formed by the upper surface of the uppermost nanosheet NS3 of the channel pattern CP and the side surfaces of the first interlayer insulating film 120. In this case, the first insulating pattern (e.g., IL1 of FIGS. 2 and 3) may not be formed, but the disclosure is not limited thereto. For example, the first insulating pattern may be formed on a side surface of the first passivation pattern 130 in the second direction D2.

According to some embodiments, a thickness of the outer passivation pattern 134 may be greater than that of each of the nanosheets NS1, NS2, and NS3 between the inner passivation patterns 132. For example, a distance from the upper surface of the outer passivation pattern 134 to the upper surface of the uppermost nanosheet NS3 of the channel pattern CP (or the lower surface of the outer passivation pattern 134) may be greater than a distance from the upper surface to the lower surface of each of the nanosheets NS1, NS2, and NS3 disposed between the inner passivation patterns 132.

The thickness of the outer passivation pattern 134 may be the same as a distance between opposite surfaces of the outer passivation pattern 134 in the third direction D3. The thickness of each of the nanosheets NS1, NS2, and NS3 may be the same as a distance between opposite surfaces of the nanosheets in the third direction D3.

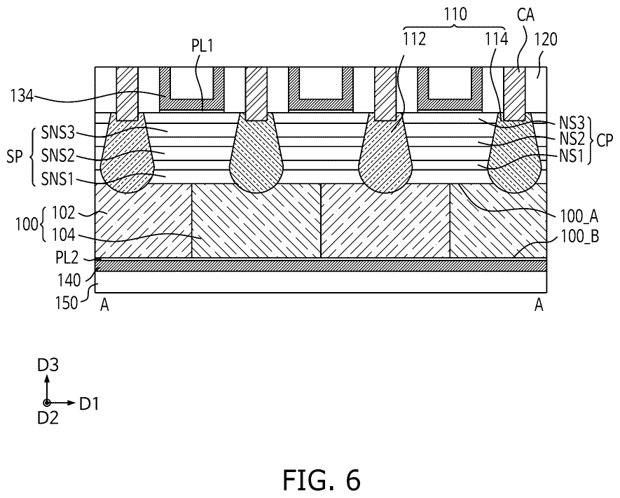

FIG. 6 is a cross-sectional view of a semiconductor device according to some embodiments. For reference, FIG. 6 may be a diagram corresponding to a cross-sectional view taken along line A-A of FIG. 1. The semiconductor device of FIG. 6 may be the same as or substantially the same as the semiconductor device described with reference to FIGS. 1 to 4, except for the shape of the impurity pattern 110 and the absence of the inner passivation pattern (e.g., 132 of FIG. 2). For convenience of explanation, a description of features that are the same as or substantially the same to those described previously may be omitted and different configurations from those described in FIGS. 1 to 4 will be mainly explained.

According to some embodiments, the channel pattern CP and a sacrificial film pattern SP may be alternately stacked on the substrate 100 along the third direction D3. For example, the channel pattern CP may include a plurality of nanosheets NS1, NS2, and NS3. Further, the sacrificial film pattern SP may include a plurality of sacrificial film nanosheets SNS1, SNS2, and SNS3. The plurality of nanosheets NS1, NS2, and NS3 and the plurality of sacrificial film nanosheets SNS1, SNS2, and SNS3 may be alternately stacked on the substrate 100.

According to some embodiments, the impurity pattern 110 may be formed through an ion implantation process. For example, the impurity pattern 110 may be formed through the ion implantation process for a stacked structure of the channel pattern CP and the sacrificial film pattern SP. The impurity pattern 110 may be configured to act as the diode role of the PN junction structure formed between the first well 102 and the second well 104. For example, the impurity pattern 110 may serve as a path for electrical connection between the contact CA and the wells 102 and 104. The impurity pattern 110 may be shaped such that it increases in width in a direction from an upper surface to a predetermined depth, then gradually decreases beyond the predetermined depth, and forms a convex curved surface at a lower side.

According to some embodiments, the first passivation pattern 130 may include the outer passivation pattern 134. The outer passivation pattern 134 may be disposed on a stacked structure of the channel pattern CP and the sacrificial film pattern SP. For example, the outer passivation pattern 134 may be disposed on the uppermost nanosheet NS3 of the channel pattern CP.

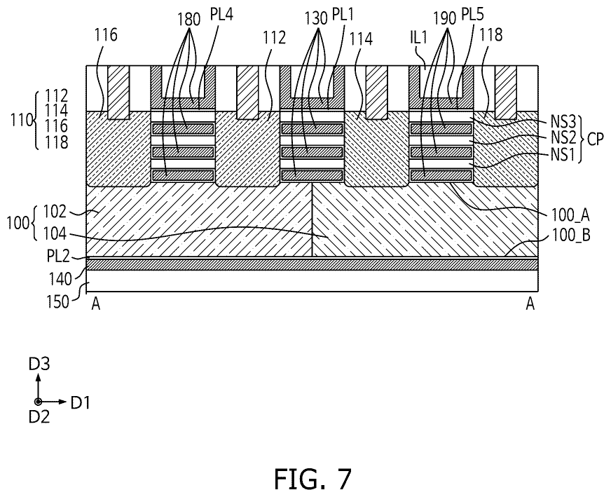

FIG. 7 is a cross-sectional view of a semiconductor device according to some embodiments. For reference, FIG. 7 may be a diagram corresponding to a cross-sectional view taken along line A-A of FIG. 1. For convenience of explanation, a description of features that are the same as or substantially similar to those described previously may be omitted and different configurations from those described in FIGS. 1 to 6 will be mainly explained.

According to some embodiments, the semiconductor device may include the first impurity pattern 112, the second impurity pattern 114, a third impurity pattern 116, and a fourth impurity pattern 118.

The first impurity pattern 112 and the third impurity pattern 116 may be disposed on the first well 102, and the second impurity pattern 114 and the fourth impurity pattern 118 may be disposed on the second well 104. Each of the first to fourth impurity patterns 112, 114, 116 and 118 may be spaced apart from each other in the first direction D1.

The conductivity type of the first impurity pattern 112 and the third impurity pattern 116 may be opposite to that of the second impurity pattern 114 and the fourth impurity pattern 118 (e.g., an opposite type). For example, the first impurity pattern 112 and the third impurity pattern 116 may include p-type impurities, and the second impurity pattern 114 and the fourth impurity pattern 118 may include n-type impurities. In another example, the first impurity pattern 112 and the third impurity pattern 116 may include n-type impurities, and the second impurity pattern 114 and the fourth impurity pattern 118 may include p-type impurities. The n-type impurities may include materials such as phosphorus (P), arsenic (As), or antimony (Sb). The p-type impurities may include a material such as boron (B), gallium (Ga), or aluminum (Al). However, the disclosure is not limited to the above.

The first impurity pattern 112 and the second impurity pattern 114 having the opposite conductivity types may be disposed opposite to each other in the first direction (e.g., on opposite sides of a passivation pattern in the first direction). The first impurity pattern 112 and the third impurity pattern 116 having the same conductivity type may be disposed opposite to each other in the first direction (e.g., on opposites side of another passivation pattern in the first direction). The second impurity pattern 114 and the fourth impurity pattern 118 having the same conductivity type may be disposed opposite to each other in the first direction (e.g., on opposite sides of another passivation pattern in the first direction).

According to some embodiments, the semiconductor device may include a first passivation pattern 130, a second passivation pattern 140, a fourth passivation pattern 180, and a fifth passivation pattern 190. The second passivation pattern 140 may be the same as that described with reference to FIGS. 1 to 3.

The first passivation pattern 130, the fourth passivation pattern 180, and the fifth passivation pattern 190 may be disposed on the first surface 100_A of the substrate 100. For example, the first passivation pattern 130, the fourth passivation pattern 180, and the fifth passivation pattern 190 may be disposed on the wells 102 and 104 of the substrate 100 and on the device isolation film 105.

The first passivation pattern 130 may be disposed between the first impurity pattern 112 and the second impurity pattern 114. The fourth passivation pattern 180 may be disposed between the first impurity pattern 112 and the third impurity pattern 116. The fifth passivation pattern 190 may be disposed between the second impurity pattern 114 and the fourth impurity pattern 118.

The materials of the passivation patterns 130, 140, 180, and 190 may be the same as the materials of the passivation patterns described above with reference to FIGS. 1 to 3.

According to some embodiments, the semiconductor device may include the first passivation insulating film PL1, the second passivation insulating film PL2, a fourth passivation insulating film PL4, and a fifth passivation insulating film PL5. The first passivation insulating film PL1 and the second passivation insulating film PL2 may include the same material as described with reference to FIGS. 1 to 3.

The fourth passivation insulating film PL4 may be disposed on the fourth passivation pattern 180. The fourth passivation insulating film PL4 may be disposed between the fourth passivation pattern 180 and the first impurity pattern 112, and disposed between the fourth passivation pattern 180 and the third impurity pattern 116.

The fifth passivation insulating film PL5 may be disposed on the fifth passivation pattern 190. The fifth passivation insulating film PL5 may be disposed between the fifth passivation pattern 190 and the second impurity pattern 114, and disposed between the fifth passivation pattern 190 and the fourth impurity pattern 118.

In addition to the foregoing, details of the placement of the fourth passivation insulating film PL4 and the fifth passivation insulating film PL5 may be the same as or similar to those of the first passivation insulating film PL1 described above with reference to FIGS. 1 to 3.

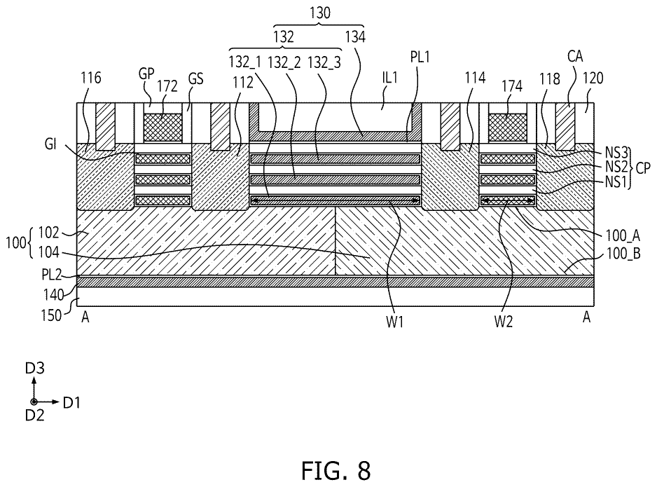

FIG. 8 is a cross-sectional view of a semiconductor device according to some embodiments. For reference, FIG. 8 may be a diagram corresponding to a cross-sectional view taken along line A-A of FIG. 1. The semiconductor device of FIG. 8 may be the same or substantially the same as that described with reference to FIG. 7, except that the gate electrode patterns 172 and 174 are disposed between the first impurity pattern 112 and the third impurity pattern 116 and between the second impurity pattern 114 and the fourth impurity pattern 118. For convenience of explanation, a description of features that are the same as or substantially the same to those described previously may be omitted and different configurations from those described in FIGS. 1 to 7 will be mainly explained.

According to some embodiments, the semiconductor device may further include a first gate electrode pattern 172, a second gate electrode pattern 174, a gate insulating film GI, a gate capping pattern GP, and a gate spacer GS.

The first gate electrode pattern 172 may be disposed between the first impurity pattern 112 and the third impurity pattern 116. The second gate electrode pattern 174 may be disposed between the second impurity pattern 114 and the fourth impurity pattern 118.

Each of the first gate electrode pattern 172 and the second gate electrode pattern 174 may surround each of the nanosheet NS1, NS2, and NS3 of the channel pattern CP, and may include, in a cross-section (e.g., A-A cross-section) of the semiconductor device, a plurality of gate electrodes disposed and spaced apart from each other on the substrate 100. The plurality of gate electrodes may be alternately stacked with the plurality of the nanosheets NS1, NS2, and NS3. The gate electrode patterns 172 and 174 may include a lower region adjacent to the impurity patterns 112, 114, 116 and 118 in the first direction D1 and an upper region disposed on a side surface of the gate spacer GS.

The gate electrode patterns 172 and 174 may include at least one of metal, metal alloy, conductive metal nitride, metal silicide, doped semiconductor material, conductive metal oxide, or conductive metal oxynitride.

The gate insulating film GI may be disposed on the gate electrode patterns 172 and 174. For example, the gate insulating film GI may be disposed between the gate electrode patterns 172 and 174 and the channel pattern CP. The gate insulating film GI may be disposed between the first gate electrode pattern 172 and the first impurity pattern 112, and disposed between the first gate electrode pattern 172 and the third impurity pattern 116. The gate insulating film GI may be disposed between the second gate electrode pattern 174 and the second impurity pattern 114, and disposed between the second gate electrode pattern 174 and the fourth impurity pattern 118.

The gate insulating film GI may include, for example, silicon oxide, silicon oxynitride, silicon nitride, or a high-k material having a higher dielectric constant than silicon oxide.

The gate capping pattern GP may be disposed on upper surfaces of the gate electrode patterns 172 and 174. The gate capping pattern GP may be disposed between the gate spacers GS. A side surface of the gate capping pattern GP may be in contact with the gate spacer GS. For example, the gate capping pattern GP may include at least one of silicon nitride (SiN), silicon oxynitride (SiON), silicon carbonitride (SiCN), silicon oxycarbonitride (SiOCN), or a combination thereof.

The gate spacers GS may be disposed on upper regions of the gate electrode patterns 172 and 174 and on the side surface of the gate capping pattern GP. For example, the gate spacers GS may extend along the side surfaces of the upper regions of the gate electrode patterns 172 and 174 and along the side surface of the gate capping pattern GP. For example, the gate spacer GS may include at least one of silicon nitride (SiN), silicon nitride oxide (SiON), silicon oxide (SiO₂), silicon carbonate (SiOCN), silicon boron nitride (SiBN), silicon boron oxide (SiOBN), silicon oxycarbide (SiOC), or a combination thereof.

According to some embodiments, a first width W1 of the first passivation pattern 130 may be greater than a second width W2 of one of the gate electrode patterns 172 and 174. The first width W1 of the first passivation pattern 130 may be the same as a distance between opposite surfaces of the first passivation pattern 130 in the first direction D1. The second width W2 of one of the gate electrode patterns 172 and 174 may be the same as a distance between opposite surfaces of each of the gate electrode patterns 172 and 174 in the first direction D1.

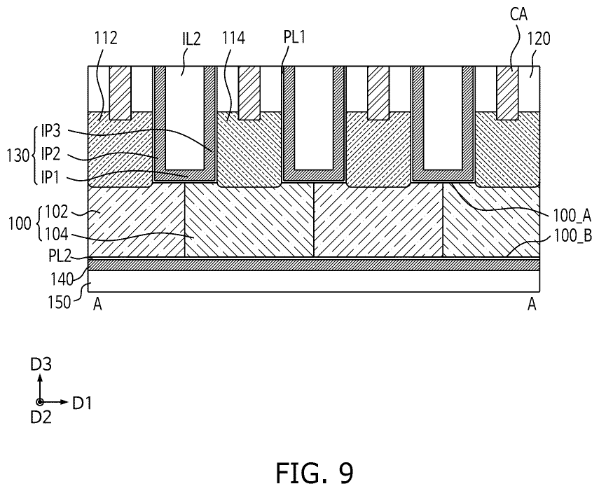

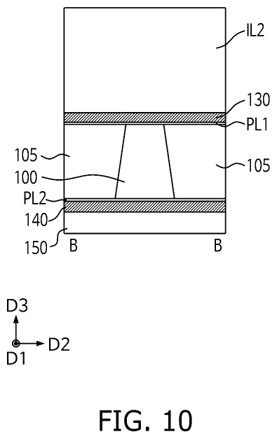

FIGS. 9 and 10 are diagrams illustrating a cross-section of a semiconductor device according to some embodiments. For reference, FIG. 9 may be a diagram corresponding to a cross-sectional view taken along line A-A of FIG. 1. FIG. 10 may be a diagram corresponding to a cross-sectional view taken along line B-B of FIG. 1. The semiconductor devices of FIGS. 9 and 10 may be the same as or substantially the same as the semiconductor device described with reference to FIGS. 1 to 4, except for the different shapes of the first passivation pattern 130 and the first passivation insulating film PL1 and the absence of the channel pattern (e.g., CP of FIG. 2) and the first insulating pattern IL1. For convenience of explanation, a description of features that are the same as or substantially the same to those described previously may be omitted and different configurations from those described in FIGS. 1 to 4 will be mainly explained.

The first passivation pattern 130 may be disposed on the first surface 100_A of the substrate 100. For example, the first passivation pattern 130 may be disposed between the first impurity pattern 112 and the second impurity pattern 114.

According to some embodiments, the first passivation pattern 130 may include a first portion IP1 disposed on the first surface 100_A of the substrate 100, a second portion IP2 extending from one end of the first portion IP1 and intersecting with the first portion IP1, and a third portion IP3 extending from the other end of the first portion IP1 and intersect with the first portion IP1. The first portion IP1 may be disposed on the upper surfaces of the substrate 100 and the device isolation film 105. Further, the second portion IP2 and the third portion IP3 may extend generally in the third direction D3 along side surfaces of the impurity patterns 112 and 114 and the first interlayer insulating film 120.

According to some embodiments, the semiconductor device may further include a second insulating pattern IL2. The second insulating pattern IL2 may be disposed on the first passivation pattern 130. The second insulating pattern IL2 may be disposed on the first portion IP1, and disposed between the second portion IP2 and the third portion IP3. The second insulating pattern IL2 may include at least one of silicon oxide (SiO), silicon nitride (SiN), or silicon oxynitride (SiON), but the disclosure is not limited thereto.

The first passivation insulating film PL1 may be disposed on the first passivation pattern 130. For example, the first passivation insulating film PL1 may be disposed between the first passivation pattern 130 and the first surface 100_A of the substrate 100. For example, the first passivation insulating film PL1 may be disposed between the first passivation pattern 130 and the first impurity pattern 112, and disposed between the first passivation pattern 130 and the second impurity pattern 114. For example, the first passivation insulating film PL1 may be disposed between the first passivation pattern 130 and the first interlayer insulating film 120. The first passivation pattern 130 may be prevented from contact with the substrate 100 and the impurity patterns 112 and 114 by the first passivation insulating film PL1.

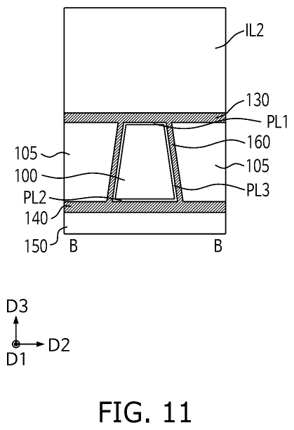

FIG. 11 is a cross-sectional view of a semiconductor device according to some embodiments. For reference, FIG. 11 may be a diagram corresponding to a cross-sectional view taken along line B-B in FIG. 1. For convenience of explanation, a description of features that are the same as or substantially the same as those described previously may be omitted and different configurations from those described with reference to FIGS. 9 and 10 will be mainly explained.

According to some embodiments, the semiconductor device may further include the third passivation pattern 160 and the third passivation insulating film PL3.

The third passivation pattern 160 may be disposed on the side surface of the fin region of the substrate 100. For example, the third passivation pattern 160 may extend along the side surface of the substrate 100. The fin region may extend in the first direction D1, and the side surface of the fin region may represent a surface corresponding to the second direction D2 of the substrate 100. Further, the width of the upper surface of the fin region may be narrower than that of the lower surface of the fin region.

The third passivation insulating film PL3 may be disposed between the third passivation pattern 160 and the substrate 100. For example, the third passivation insulating film PL3 may be disposed between the third passivation pattern 160 and the side surface of the fin region of the substrate 100. The third passivation pattern 160 may be prevented from contact with the substrate 100 by the third passivation insulating film PL3.

In some embodiments, the third passivation pattern 160 may be connected to the first passivation pattern 130. Further, the third passivation pattern 160 may be connected to the second passivation pattern 140. Accordingly, the first passivation pattern 130, the second passivation pattern 140, and the third passivation pattern 160 may be integrally formed.

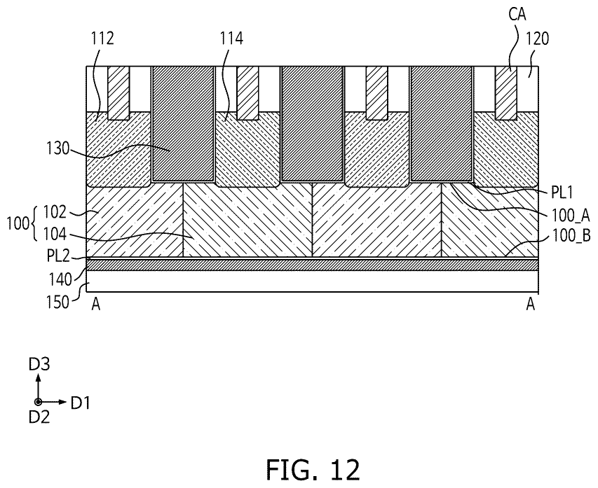

FIG. 12 is a cross-sectional view of a semiconductor device according to some embodiments. For reference, FIG. 12 may be a diagram corresponding to a cross-sectional view taken along line A-A of FIG. 1. The semiconductor device of FIG. 12 may be substantially the same as the semiconductor device described with reference to FIGS. 9 to 11, except for the shape of the first passivation pattern 130. For convenience of explanation, a description of features that are the same as or substantially the same as those described previously may be omitted and different configurations from those described in FIGS. 9 to 11 will be mainly explained.

According to some embodiments, the first passivation pattern 130 may fill a space formed by the first surface 100_A of the substrate 100 and the side surfaces of the impurity patterns 112 and 114. For example, the first passivation pattern 130 may extend in the third direction D3 from a vertical level corresponding to the first surface 100_A of the substrate 100 to a vertical level corresponding to an upper surface of the first interlayer insulating film 120.

In this case, the second insulating pattern (e.g., IL2 of FIGS. 9 and 10) may not be formed. However, the disclosure is not limited to the above.

In another aspect, the first passivation pattern 130 may be formed to extend in the third direction D3 from the vertical level corresponding to the first surface 100_A of the substrate 100 to a vertical level corresponding to the upper surfaces of the impurity patterns 112 and 114, and in this case, the second insulating pattern may be disposed on the first passivation pattern 130.

According to some embodiments, the vertical level of the upper surface of the first passivation pattern 130 may be the same as the vertical level of the upper surface of one of the impurity patterns 112 and 114, or may be higher than the vertical level of the upper surface of one of the impurity patterns 112 and 114.

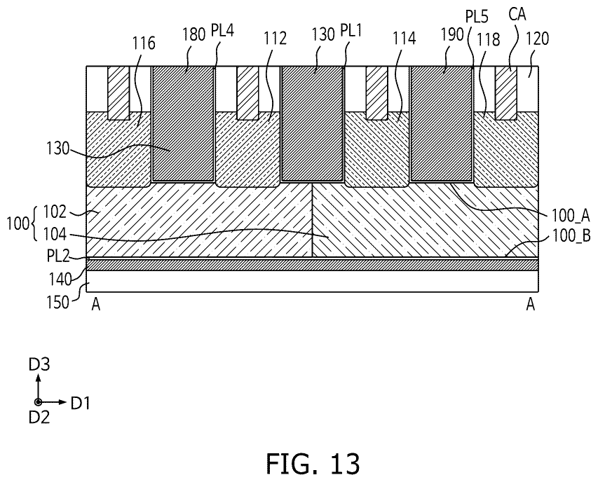

FIG. 13 is a cross-sectional view of a semiconductor device according to some embodiments. For reference, FIG. 13 may be a diagram corresponding to a cross-sectional view taken along line A-A of FIG. 1. Hereinafter, for convenience of explanation, a description of features that are the same as or substantially the same as those described previously may be omitted and configurations different from those described with reference to FIGS. 1 to 7 and 9 to 12 will be mainly explained.

According to some embodiments, the semiconductor device may include the first impurity pattern 112, the second impurity pattern 114, the third impurity pattern 116, and the fourth impurity pattern 118. The first impurity pattern 112, the second impurity pattern 114, the third impurity pattern 116, and the fourth impurity pattern 118 may be the same as or substantially the same as those described with reference to FIG. 7.

According to some embodiments, the semiconductor device may include the first passivation pattern 130, the second passivation pattern 140, the fourth passivation pattern 180, and the fifth passivation pattern 190. The first passivation pattern 130 may be the same as or substantially the same as that described with reference to FIG. 12. Further, the second passivation pattern 140 may be the same as or substantially the same as that described with reference to FIGS. 1 to 3.

The fourth passivation pattern 180 may be disposed between the first impurity pattern 112 and the third impurity pattern 116. According to some embodiments, the fourth passivation pattern 180 may fill a space formed by the first surface 100_A of the substrate 100 and the side surfaces of the first impurity pattern 112 and the third impurity pattern 116. For example, the fourth passivation pattern 180 may extend in the third direction D3 from a vertical level corresponding to the first surface 100_A of the substrate 100 to a vertical level corresponding to the upper surface of the first interlayer insulating film 120.

The fifth passivation pattern 190 may be disposed between the second impurity pattern 114 and the fourth impurity pattern 118. According to some embodiments, the fifth passivation pattern 190 may fill a space formed by the first surface 100_A of the substrate 100 and the side surfaces of the second impurity pattern 114 and the fourth impurity pattern 118. For example, the fifth passivation pattern 190 may extend in the third direction D3 from the vertical level corresponding to the first surface 100_A of the substrate 100 to the vertical level corresponding to the upper surface of the first interlayer insulating film 120.

According to some embodiments, the semiconductor device may include the first passivation insulating film PL1, the second passivation insulating film PL2, the fourth passivation insulating film PL4, and the fifth passivation insulating film PL5. The first passivation insulating film PL1 may be the same as or substantially the same as that described with reference to FIG. 9. The second passivation insulating film PL2 may be the same as or substantially the same as that described with reference to FIGS. 1 to 3.

The fourth passivation insulating film PL4 may be disposed on the fourth passivation pattern 180. The fourth passivation insulating film PL4 may be disposed between the fourth passivation pattern 180 and the first impurity pattern 112, and disposed between the fourth passivation pattern 180 and the third impurity pattern 116.

The fifth passivation insulating film PL5 may be disposed on the fifth passivation pattern 190. The fifth passivation insulating film PL5 may be disposed between the fifth passivation pattern 190 and the second impurity pattern 114, and disposed between the fifth passivation pattern 190 and the fourth impurity pattern 118.

In addition to the foregoing, details of the placement of the fourth passivation insulating film PL4 and the fifth passivation insulating film PL5 may be the same as or similar to those of the first passivation insulating film PL1 described above with reference to FIG. 12.

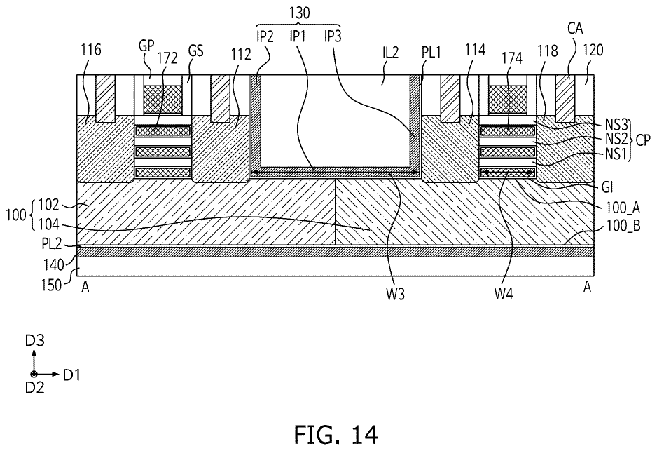

FIG. 14 is a cross-sectional view of a semiconductor device according to some embodiments. For reference, FIG. 14 may be a diagram corresponding to a cross-sectional view taken along line A-A of FIG. 1.

The semiconductor device of FIG. 14 may be substantially the same as or the same as the semiconductor device described with reference to FIG. 8, except for the different shapes of the first passivation pattern 130 and the first passivation insulating film PL1, removal of the channel pattern CP between the first impurity pattern 112 and the second impurity pattern 114, and absence of the first insulating pattern IL1.

Further, each of the first passivation pattern 130, the second insulating pattern IL2, and the first passivation insulating film PL1 of the semiconductor device of FIG. 14 may be the same as or substantially the same as that described with reference to FIGS. 9 and 10.

According to some embodiments, a third width W3 of the first portion IP1 of the first passivation pattern 130 may be greater than a fourth width W4 of one of the gate electrode patterns 172 and 174. The third width W3 of the first portion IP1 may be the same as a distance between opposite surfaces of the first portion IP1 in the first direction D1. The fourth width W4 of one of the gate electrode patterns 172 and 174 may be the same as a distance between opposite surfaces of each of the gate electrode patterns 172 and 174 in the first direction D1.

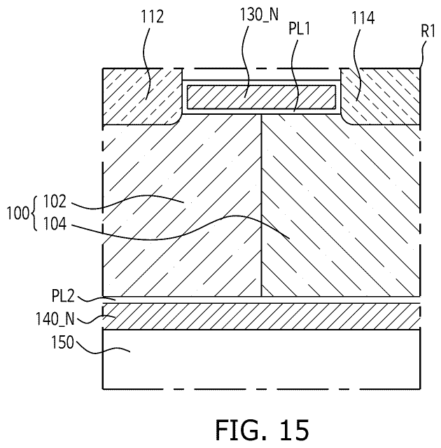

FIGS. 15 to 21 are cross-sections of a semiconductor device according to some embodiments. For reference, FIGS. 15 to 21 correspond to enlarged views of the region R1 of FIG. 2.

According to some embodiments, the first passivation pattern 130 and the second passivation pattern 140 may selectively form a negative fixed charge layer or a positive fixed charge layer according to shapes of the first well 102 and the second well 104. Hereinafter, an aspect in which the first well 102 includes a p-type conductivity type and the second well 104 includes an n-type conductivity type will be explained.

Referring to FIG. 15, a side surface of the first well 102 may be disposed on a side surface of the second well 104. In this case, the first passivation pattern 130_N and the second passivation pattern 140_N may include a negative fixed charge layer.

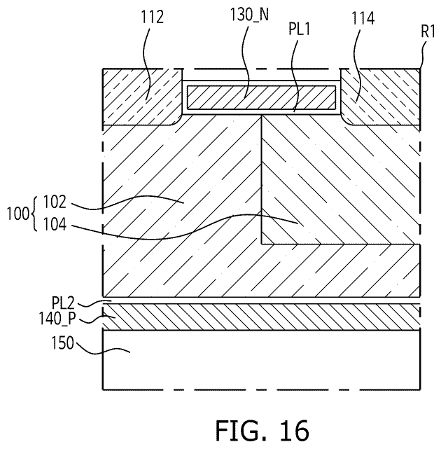

Referring to FIG. 16, the first well 102 may be disposed on the side surface and the lower surface of the second well 104. In this case, the first passivation pattern 130_N may include a negative fixed charge layer, and the second passivation pattern 140_P may include a positive fixed charge layer.

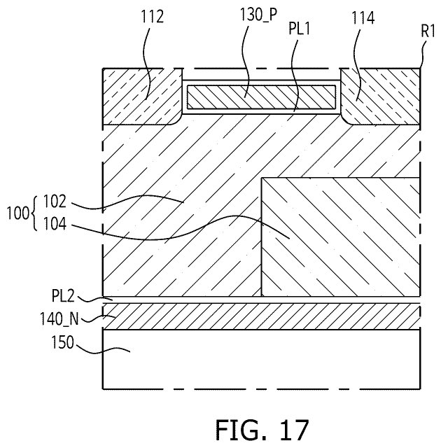

Referring to FIG. 17, the first well 102 may be disposed on the side surface and the upper surface of the second well 104. In this case, the first passivation pattern 130_P may include a positive fixed charge layer, and the second passivation pattern 140_N may include a negative fixed charge layer.

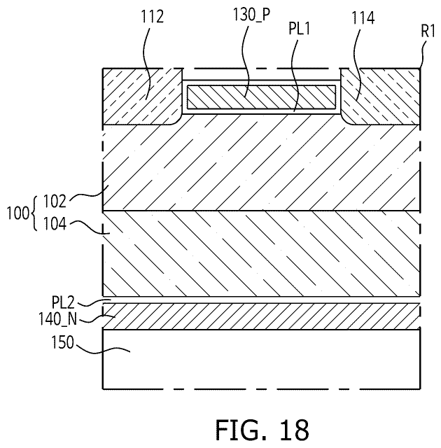

Referring to FIG. 18, the lower surface of the first well 102 may be disposed on the upper surface of the second well 104. In this case, the first passivation pattern 130_P may include a positive fixed charge layer, and the second passivation pattern 140_N may include a negative fixed charge layer.

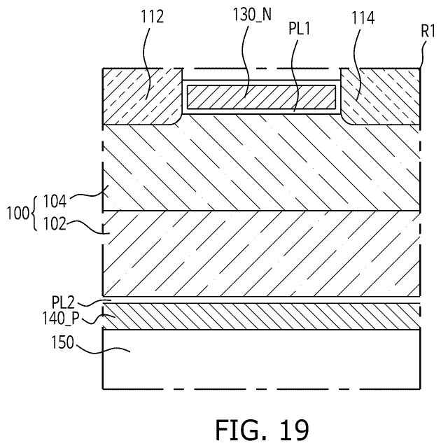

Referring to FIG. 19, the upper surface of the first well 102 may be disposed on the lower surface of the second well 104. In this case, the first passivation pattern 130_N may include a negative fixed charge layer, and the second passivation pattern 140_P may include a positive fixed charge layer.

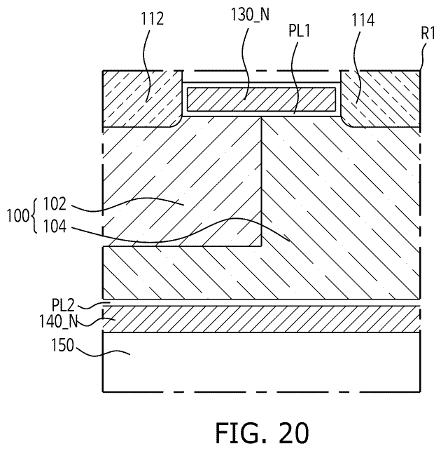

Referring to FIG. 20, the second well 104 may be disposed on the side surface and the lower surface of the first well 102. In this case, the first passivation pattern 130_N and the second passivation pattern 140_N may include a negative fixed charge layer.

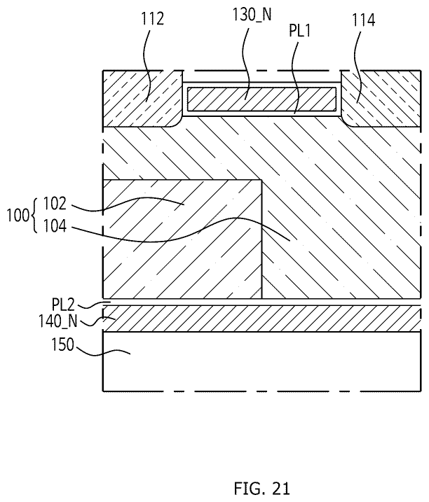

Referring to FIG. 21, the second well 104 may be disposed on the side surface and the upper surface of the first well 102. In this case, the first passivation pattern 130_N and the second passivation pattern 140_N may include a negative fixed charge layer.

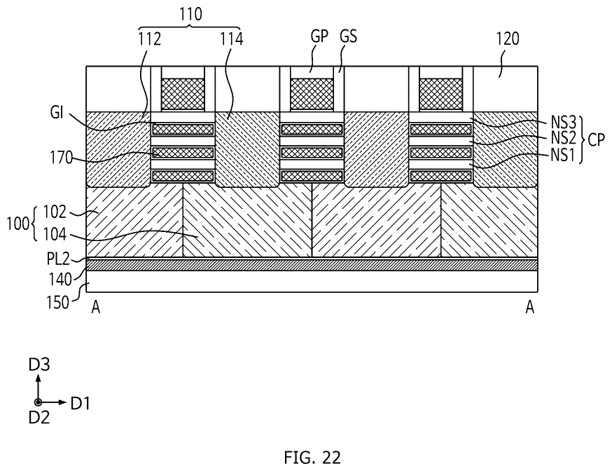

FIGS. 22 to 24 are views illustrating intermediate stages of a semiconductor device during a method for manufacturing a semiconductor device according to some embodiments. For reference, FIGS. 22 to 24 are views corresponding to a cross-sectional view taken along line A-A of FIG. 1.

The method for manufacturing the semiconductor device according to some embodiments may include providing an intermediate structure stacked on a passive device region of the substrate 100. The intermediate structure may include a gate bounded PN diode, but the disclosure is not limited thereto.

Referring to FIG. 22, the intermediate structure may include the substrate 100, the impurity pattern 110, a gate electrode pattern 170, the gate insulating film GI, the gate capping pattern GP, the gate spacer GS, the channel pattern CP, the first interlayer insulating film 120, the second passivation pattern 140, and the second passivation insulating film PL2.

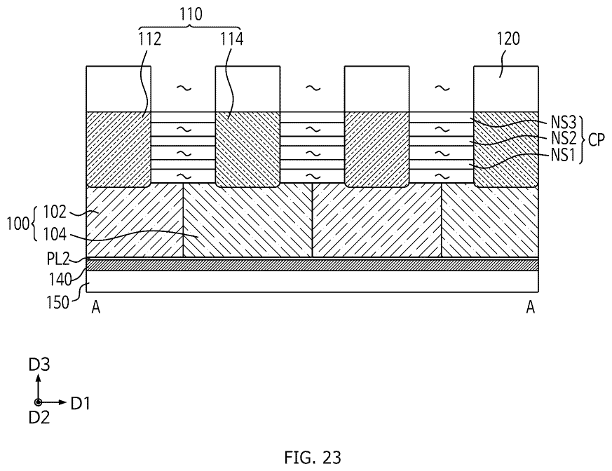

Referring to FIG. 23, the gate electrode pattern 170, the gate insulating film GI, the gate capping pattern GP, and the gate spacer GS may be patterned and removed.

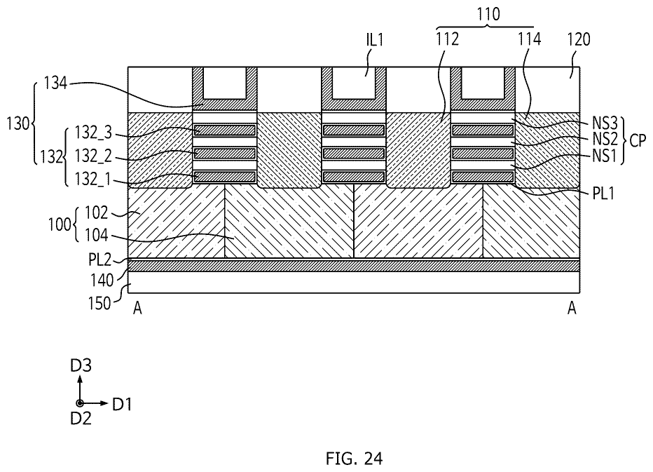

Referring to FIG. 24, the first passivation pattern 130 and the first passivation insulating film PL1 may be formed in the space from which the gate electrode pattern 170, the gate insulating film GI, the gate capping pattern GP, and the gate spacer GS have been removed. The first insulating pattern IL1 may be formed on the first passivation pattern 130. As the contact CA is formed on the impurity pattern 110, the semiconductor device described with reference to FIGS. 1 to 3 may be provided. The semiconductor device of FIGS. 4 to 8 may be manufactured using a method similar to the method described above.

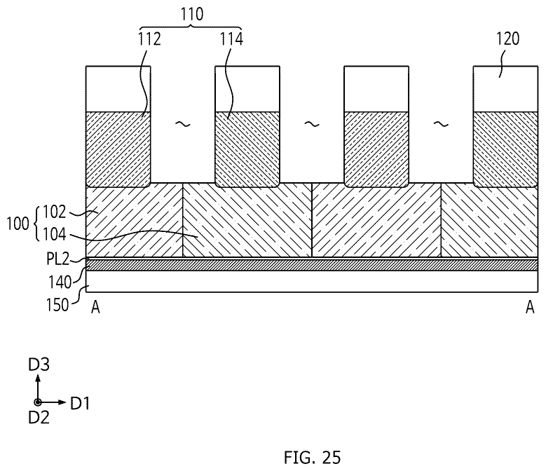

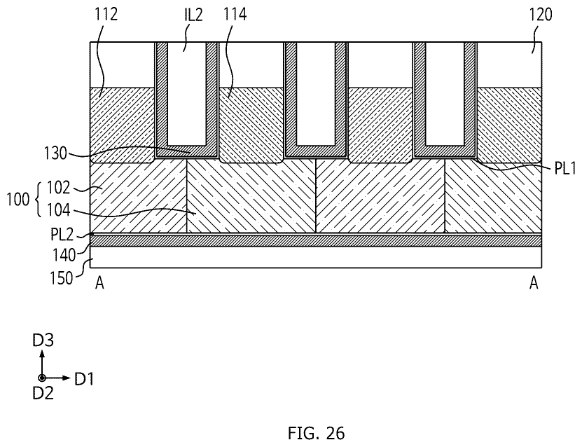

FIGS. 25 and 26 are views illustrating intermediate stages of a semiconductor device during a method for manufacturing a semiconductor device according to some embodiments. For reference, FIGS. 25 and 26 are views corresponding to a cross-sectional view taken along line A-A of FIG. 1.

The method for manufacturing the semiconductor device according to some embodiments may include providing the intermediate structure stacked on the passive device region of the substrate 100. For example, the intermediate structure described with reference to FIG. 22 may be provided.

Referring to FIG. 25, the gate electrode pattern 170, the gate insulating film GI, the gate capping pattern GP, the gate spacer GS, and the channel pattern CP may be patterned and removed.

Referring to FIG. 26, the first passivation pattern 130 and the first passivation insulating film PL1 may be formed in the space from which the gate electrode pattern 170, the gate insulating film GI, the gate capping pattern GP, the gate spacer GS, and the channel pattern CP have been removed. The second insulating pattern IL2 may be formed on the first passivation pattern 130. As the contact CA is formed on the impurity pattern 110, the semiconductor device described with reference to FIGS. 9 and 10 may be provided. The semiconductor device of FIGS. 11 to 14 may be manufactured using a method the same as or similar to the method described above.

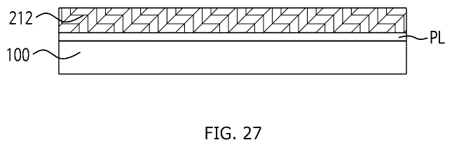

FIGS. 27 to 32 are views illustrating intermediate stages during a method for manufacturing a semiconductor device, according to some embodiments. The method for manufacturing the semiconductor device according to some embodiments may include a method for forming a passivation pattern on the substrate 100.

Referring to FIG. 27, the passivation insulating film PL may be formed on the substrate 100, and a first basic passivation layer 212 may be formed on the passivation insulating film PL.

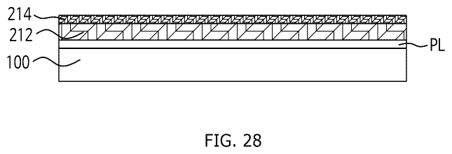

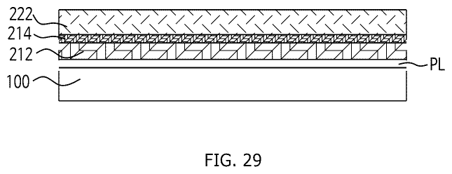

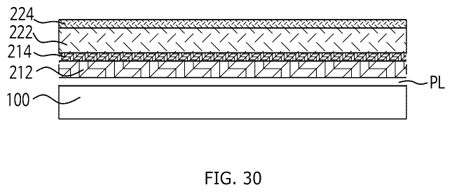

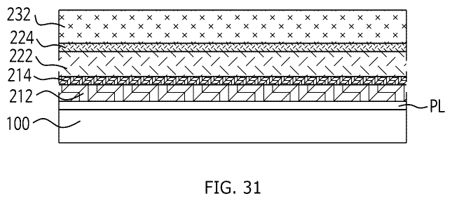

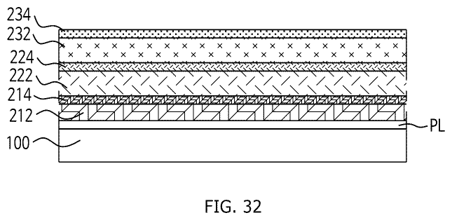

Referring to FIG. 28, a first treated passivation layer 214 may be formed through the surface treatment of the first basic passivation layer 212. Referring to FIG. 29, a second basic passivation layer 222 may be formed on the first treated passivation layer 214. Referring to FIG. 30, a second treated passivation layer 224 may be formed through the surface treatment of the second basic passivation layer 222. Referring to FIG. 31, a third basic passivation layer 232 may be formed on the second treated passivation layer 224. Referring to FIG. 32, a third treated passivation layer 234 may be formed through the surface treatment of the third basic passivation layer 232.

The surface treatment may include fluorine treatment, hydrogen treatment, nitridation, etc., and through this, the treated passivation layers 214, 224, and 234 with altered chemical composition and interfacial properties compared to the basic passivation layers 212, 222, and 232 may be formed.

The first basic passivation layer 212, the second basic passivation layer 222, and the third basic passivation layer 232 may include a high-k material having a higher dielectric constant than silicon oxide. The first basic passivation layer 212, the second basic passivation layer 222, and the third basic passivation layer 232 may include the same or different materials. Through the method described above, a passivation pattern according to the aspects of the disclosure may be formed. That is, each of the first to fifth passivation patterns according to aspects of the present disclosure may include at least one of the first basic passivation layer 212, the first treated passivation layer 214, the second basic passivation layer 222, the second treated passivation layer 224, the third basic passivation layer 232, or the third treated passivation layer 234 described with reference to FIGS. 27 to 32.

Although the present disclosure has been described above by way of certain embodiments and drawings thereof, the inventive concept is not limited thereto, and various changes and modifications can be made to the disclosed embodiments and still fall within the technical idea of the inventive concept as defined by the claims recited below.

1. A semiconductor device, comprising:
a substrate including a first well having a first conductivity type and a second well having a second conductivity type that is opposite the first conductivity type;
a first impurity pattern of the first conductivity type disposed on the first well;
a second impurity pattern of the second conductivity type disposed on the second well;
a first passivation pattern disposed between the first impurity pattern and the second impurity pattern on a first surface of the substrate; and
a second passivation pattern disposed on a second surface of the substrate opposite to the first surface of the substrate.

2. The semiconductor device according to claim 1, further comprising a channel pattern including a plurality of nanosheets stacked and spaced apart from one another on the substrate, wherein
the first passivation pattern includes an inner passivation pattern including a plurality of passivation layers with the passivation layers of the plurality of passivation layers alternately stacked with the nanosheets of the plurality of nanosheets.

3. The semiconductor device according to claim 2, wherein the first passivation pattern includes an outer passivation pattern disposed on the channel pattern.

4. The semiconductor device according to claim 3, wherein:
the outer passivation pattern includes a first portion disposed on an uppermost nanosheet of the channel pattern and extending in a first direction, a second portion extending in a second direction from a first end of the first portion in the first direction and intersecting with the first portion, and a third portion extending in the second direction from a second end of the first portion in the first direction and intersecting with the first portion; and
the semiconductor device further includes an insulating pattern disposed between the second portion and the third portion.

5. The semiconductor device according to claim 3, wherein a thickness of the outer passivation pattern is greater than a thickness of each of the nanosheets included in the inner passivation pattern.

6. The semiconductor device according to claim 1, wherein:
the first passivation pattern includes a first portion disposed on the first surface of the substrate and extending in a first direction, a second portion extending in a second direction from a first end of the first portion and intersecting with the first portion, and a third portion extending in the second direction from a second end opposite the first end of the first portion and intersecting with the first portion; and
the semiconductor device further includes an insulating pattern disposed between the second portion and the third portion.

7. The semiconductor device according to claim 1, wherein a vertical level of an upper surface of the first passivation pattern is the same as or higher than a vertical level of an upper surface of the first impurity pattern.

8. The semiconductor device according to claim 1, wherein:
a side surface of the first well is disposed on a side surface of the second well;
the first passivation pattern and the second passivation pattern include a negative fixed charge layer; and
the first conductivity type is a p-type, and the second conductivity type is an n-type.

9. The semiconductor device according to claim 1, wherein:
the first well is disposed on a side surface and a lower surface of the second well;
the first passivation pattern includes a negative fixed charge layer;
the second passivation pattern includes a positive fixed charge layer; and
the first conductivity type is a p-type, and the second conductivity type is an n-type.

10. The semiconductor device according to claim 1, wherein:
the first well is disposed on a side surface and an upper surface of the second well;
the first passivation pattern includes a positive fixed charge layer;
the second passivation pattern includes a negative fixed charge layer; and
the first conductivity type is a p-type, and the second conductivity type is an n-type.

11. The semiconductor device according to claim 1, wherein:
the first well is disposed on an upper surface of the second well;
the first passivation pattern includes a positive fixed charge layer;
the second passivation pattern includes a negative fixed charge layer; and
the first conductivity type is a p-type, and the second conductivity type is an n-type.

12. The semiconductor device according to claim 1, wherein:
the second well is disposed on a side surface and a lower surface of the first well;
the first passivation pattern and the second passivation pattern include a negative fixed charge layer; and
the first conductivity type is a p-type, and the second conductivity type is an n-type.

13. The semiconductor device according to claim 1, wherein:
the second well is disposed on a side surface and an upper surface of the first well;
the first passivation pattern and the second passivation pattern include a negative fixed charge layer; and
the first conductivity type is a p-type, and the second conductivity type is an n-type.

14. The semiconductor device according to claim 1, further comprising:
a first passivation insulating film disposed between the first passivation pattern and the substrate; and
a second passivation insulating film disposed between the second passivation pattern and the substrate.

15. The semiconductor device according to claim 1, wherein:
the substrate includes a fin region extending in a first direction;
the first well and the second well are arranged in series on the fin region;
the semiconductor device further includes a third passivation pattern disposed on a side surface of the fin region in a second direction; and
the first direction and the second direction intersect with each other.

16. A semiconductor device, comprising:
a substrate including a first well having a first conductivity type and a second well having a second conductivity type;
first and second impurity patterns of the first conductivity type disposed on the first well;
third and fourth impurity patterns of the second conductivity type disposed on the second well;
a first passivation pattern disposed on a first surface of the substrate; and
a second passivation pattern disposed on a second surface opposite to the first surface of the substrate,
wherein:
the first passivation pattern is disposed between the first impurity pattern and the third impurity pattern with the first impurity pattern at a first side of the first passivation pattern and the third impurity pattern at a second side of the first passivation pattern opposite the first side.

17. The semiconductor device according to claim 16, further comprising:
a third passivation pattern disposed between the first impurity pattern and the second impurity pattern; and
a fourth passivation pattern disposed between the third impurity pattern and the fourth impurity pattern.

18. The semiconductor device according to claim 16, further comprising:
a first gate electrode pattern disposed between the first impurity pattern and the second impurity pattern; and
a second gate electrode pattern disposed between the third impurity pattern and the fourth impurity pattern,
wherein each of the first gate electrode pattern and the second gate electrode pattern includes a plurality of gate electrodes disposed and spaced apart from each other on the substrate.

19. The semiconductor device according to claim 18, wherein a width of the first passivation pattern is greater than a width of the first gate electrode pattern.

20. A semiconductor device, comprising:
a substrate including a fin region including a first well of a first conductivity type and a second well of a second conductivity type, wherein the fin region extends in a first direction;
a first impurity pattern of the first conductivity type disposed on the first well;
a second impurity pattern of the second conductivity type disposed on the second well;
a first passivation pattern disposed on a first surface of the substrate and extending lengthwise in a second direction intersecting with the first direction;
a second passivation pattern disposed on a second surface opposite to the first surface of the substrate; and
an insulating pattern disposed on the first passivation pattern,
wherein:
the first passivation pattern is disposed between the first impurity pattern and the second impurity pattern in the second direction;
the first passivation pattern includes a first portion extending in the first direction and disposed on the first surface of the substrate, a second portion extending from a first end of the first portion along a side surface of the first impurity pattern in a third direction intersecting with the first and second directions, and a third portion extending from a second end of the first portion along a side surface of the second impurity pattern in the third direction; and
the insulating pattern is disposed between the second portion and the third portion.
